(19) United States
(12) Patent Application Publication
(10) Pub. No.: US 2023/0170283 A1
(43) Pub. Date: Jun. 1, 2023

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventor: Paolo CREMA, Vimercate (IT)

(73) Assignee: STMicroelectronics S.r.l., Agrate Brianza (MB) (IT)

(21) Appl. No.: 18/070,966

(22) Filed: Nov. 29, 2022

(30) Foreign Application Priority Data
Dec. 1, 2021 (IT) 10202100030392

(51) Int. Cl. H01L 23/495; H01L 21/56; H01L 23/498; H01L 23/00; H01L 25/065

(52) U.S. Cl. CPC H01L 23/49534; H01L 21/563; H01L 23/49822; H01L 24/18; H01L 24/48; H01L 24/73; H01L 25/0657; H01L 2224/48091; H01L 2224/48247; H01L 2924/18161; H01L 2224/73265

(57) ABSTRACT

A “double-deck” semiconductor device includes a first semiconductor chip mounted to a first surface of a leadframe, with a first wire bonding pattern and a first mass of encapsulating material molded onto the first surface of the leadframe when the leadframe is in a first spatial orientation. The leadframe with the first semiconductor chip and the first wire bonding pattern encapsulated and thus protected by the first mass of encapsulating material is then turned over to a second spatial orientation. A second semiconductor chip is attached to the second surface of the leadframe, with a second wire bonding pattern and a second mass of encapsulating material, different from the first mass of encapsulating material molded onto the second surface of the leadframe.

### PRIORITY CLAIM

This application claims the priority benefit of Italian Application for Patent No. 102021000030392, filed on Dec. 1, 2021, the content of which is hereby incorporated by reference in its entirety to the maximum extent allowable by law.

### TECHNICAL FIELD

The description relates to semiconductor devices.

One or more embodiments can be applied to semiconductor power devices for the automotive sector, for instance.

### BACKGROUND

Even in the presence of an ever-increasing use of Quad-Flat No-leads (QFN) packages for semiconductor devices, a remarkable interest still exists for conventional Quad Flat Package (QFP) solutions. A prevailing trend in such plastic packages involves reducing space occupation and increasing performance. For instance, semiconductor dice with increased functionality can be provided and/or a higher number of dice can be integrated in a same package.

So-called “double-deck” packages (that is, arrangements including semiconductor chips or dice mounted on both sides of a substrate such as a leadframe) facilitate achieving small package dimensions.

A “double-deck” arrangement of dice is advantageous in comparison with devices where plural semiconductor chips or dice are mounted side-by-side on a single face of a substrate such as a leadframe and also in comparison with devices where plural semiconductor chips or dice are stacked one onto another again on a single face of a substrate.

While conceptually similar to producing conventional printed circuit boards or PCBs “populated” with semiconductor devices on both sides, manufacturing “double-deck” semiconductor device packages is faced with a number of critical issues.

For instance, a first wire bonding pattern provided on one side of the substrate may require to be protected while a second wire bonding pattern is provided on the other side of the substrate. This approach is complex from the point of view of manufacturing.

Also, manufacturing “double-deck” semiconductor device packages may involve special/complex leadframes or wire bonding tools.

There is a need in the art to contribute in overcoming the drawbacks outlined in the foregoing.

### SUMMARY

One or more embodiments relate to a method.

One or more embodiments relate to a corresponding semiconductor device.

In certain embodiments, a first integrated circuit chip is mounted on a first face of a leadframe and provided with a wire-bonding pattern, with a package molding compound half-molded thereon (via film-assisted molding, for instance). Then the arrangement is turned over (by “flipping” the leadframe) and a second integrated circuit die is mounted on the second face of the leadframe and provided with a (second) wire-bonding pattern (aluminum wire, for instance) via an ultrasonic wire bonding technique. Further package molding compound is then half-molded onto the second face of the leadframe (via standard molding in a second mold, for instance) to complete the package.

The examples presented herein facilitate producing small-outline double-deck power devices (power integrated circuit die on one side, signal/controller integrated circuit die on the other side) in QFP format.

The examples presented herein facilitate multi-die assembly in a production environment within the framework of a reliable process flow.

To that effect, certain examples presented herein rely on a dual-mold process that facilitates protecting a first die assembled and encapsulated in a first mass of molding material on a first face of a substrate so that the first die will not be damaged by die attachment and wire bonding operations performed on the other face of the substrate.

### BRIEF DESCRIPTION OF THE DRAWINGS

One or more embodiments will now be described, by way of example only, with reference to the annexed figures, wherein:

FIG. 1 is sectional view across a semiconductor device according to embodiments of the present description;

FIGS. 2A to 2D are sectional views across various semiconductor devices according to embodiments of the present description;

FIGS. 3A to 3I are exemplary of steps in embodiments of the present description; and

FIG. 4 is a flow chart exemplary of a possible sequence of steps in embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Throughout the figures, reference 10 denotes as a whole a “double-deck” semiconductor device.

As illustrated, the device 10 comprises a substrate 12 such as a leadframe including a die pad portion 12A with an array of electrically conductive leads 12B arranged around the die pad 12A. As illustrated the leads are bent into an (inverted) gull-wing shape.

The designation “leadframe” (or “lead frame”) is currently used (see, for instance the USPC Consolidated Glossary of the United States Patent and Trademark Office) to indicate a metal frame that provides support (e.g., at a die pad 12A) for an integrated circuit chip or die (these terms are used herein as synonyms) as well as electrical leads such as 12B to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

As illustrated, the device 10 comprises semiconductor integrated circuit chips or dice 141, 142 (as noted, these terms are used herein as synonyms) mounted at the die pad 12A on the opposed (sur)faces of the leadframe or substrate 12.

This may be via die attachment material 1410, 1420.

Wire bonding patterns 161, 162 provide electrical connection of the chips or dice 141, 142 to the leads 12B.

Masses of package molding compound (an epoxy resin, for instance) 181, 182 are molded on both surfaces of the leadframe 12 to provide an isolating encapsulation for the chips or dice 141, 142 and the wire bonding patterns 161, 162 associated therewith.

For simplicity, a single chip or die 141, 142 is shown mounted at each surface of the leadframe 12. In certain embodiments, plural chips or dice can be mounted on either surface or both surfaces of the leadframe 12.

It is otherwise noted that the general structure of a “double-deck” device as discussed so far can be regarded as conventional in the art, as witnessed by documents such as U.S. Pat. Nos. 5,034,350, 6,677,665, 6,76,079 or 6,955,941 (incorporated herein by reference).

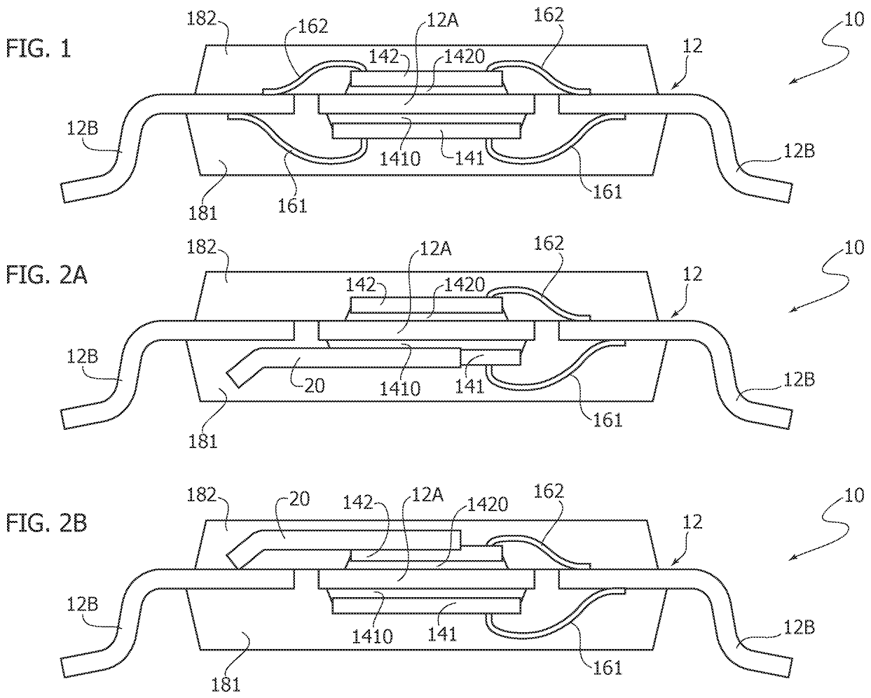

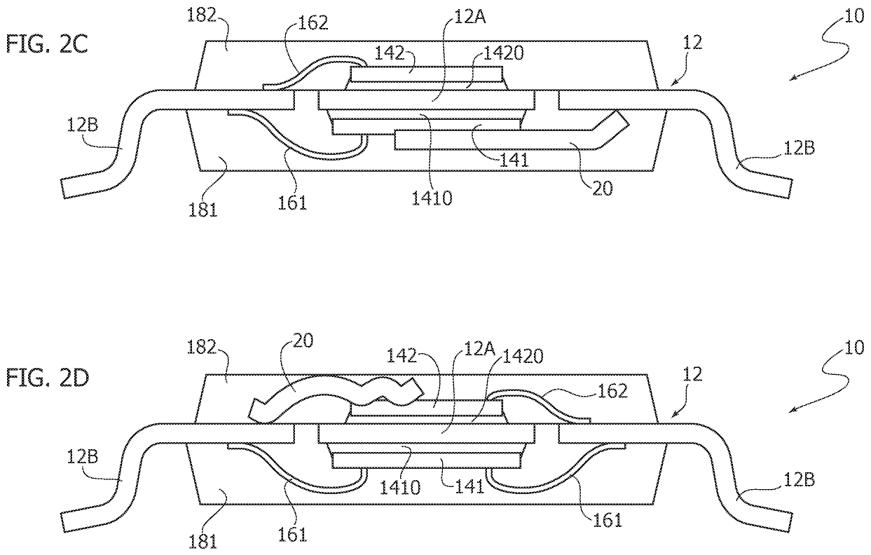

FIGS. 2A to 2D are illustrative of various examples where a device 10 as illustrated in FIG. 1 includes, in a manner known to those of skill in the art, various types of heat spreaders 20 that can be embedded in either or both the encapsulation masses 181, 182.

In FIGS. 2A to 2D, parts or elements like parts or elements already discussed in connection with FIG. 1 are indicated with like reference symbols, and a corresponding description will not be repeated for brevity. It will be otherwise appreciated that the examples herein are mainly concerned with providing a double-deck semiconductor device rather than with possible details of such a structure.

The following description will thus be provided by referring primarily to the device structure exemplified in FIG. 1, being otherwise understood that the description also applies to devices as exemplified in FIGS. 2A to 2D.

While conceptually attractive for various reasons, effectively manufacturing a “double-deck” structure as exemplified in FIG. 1 or FIGS. 2A to 2D ends up by being “easier said than done”. In that respect one must keep in mind that semiconductor devices as considered herein are not assembled by hand. Semiconductor devices as considered herein are manufactured on a large scale in highly automated processes. Even a relatively minor change or simplification in such a process may lead to quite significant improvements.

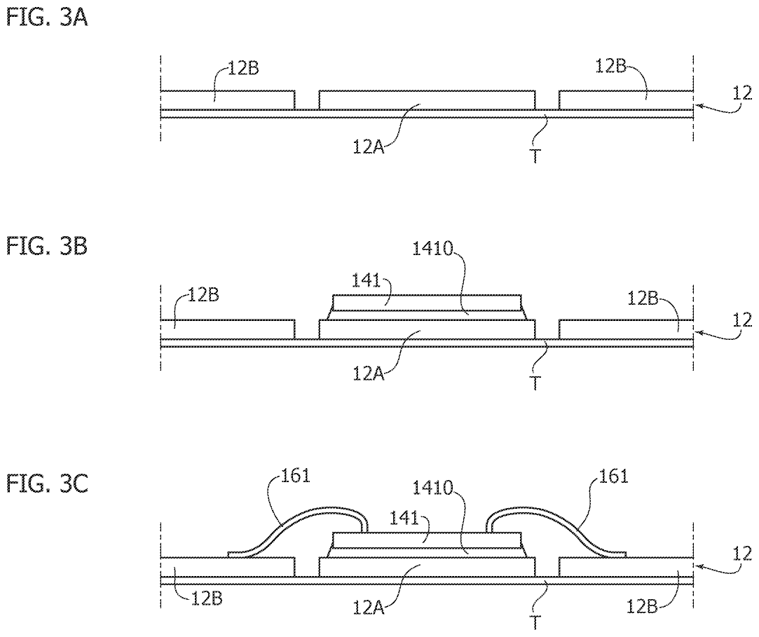

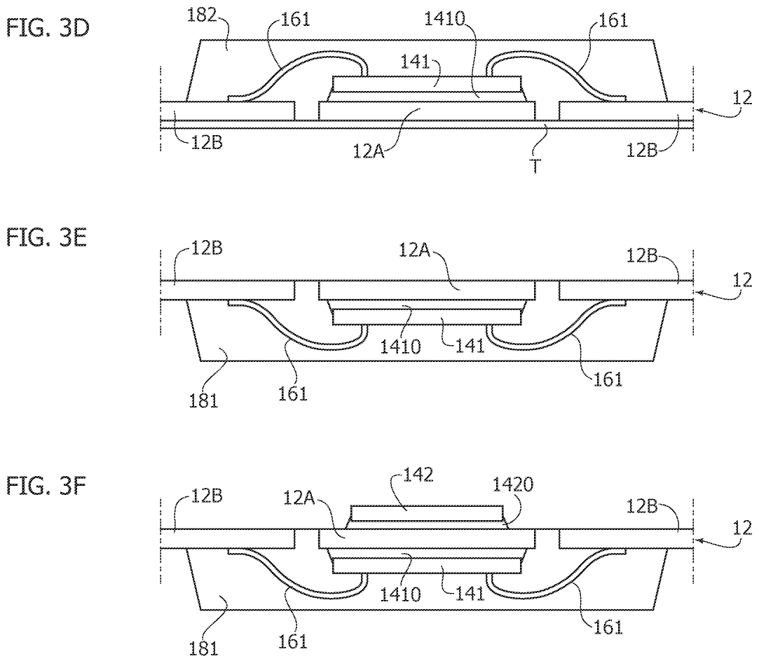

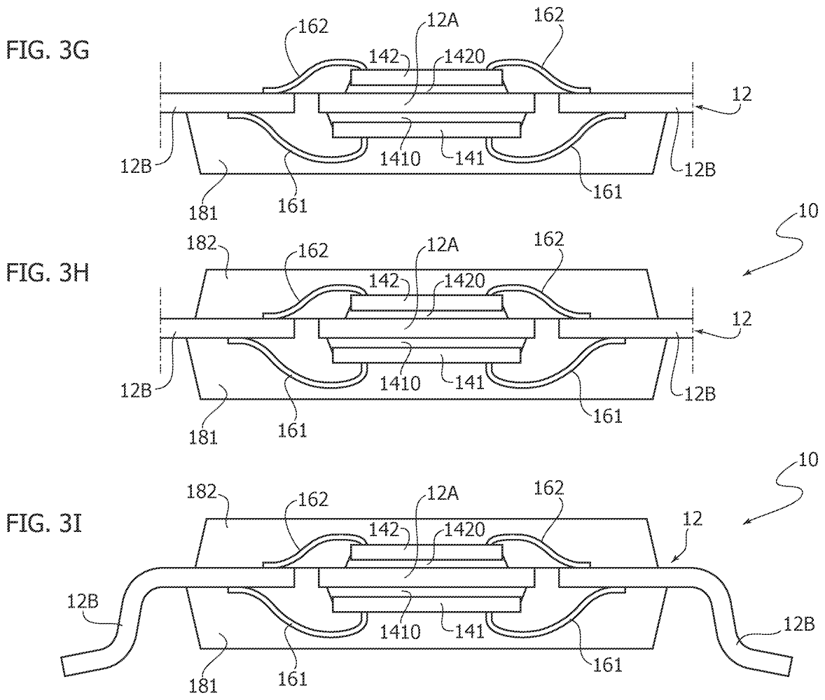

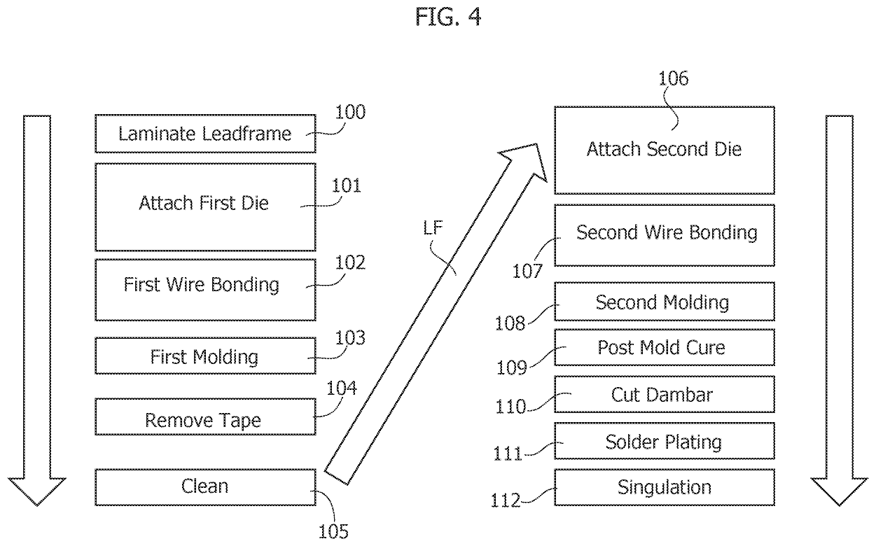

FIGS. 3A to 3I are exemplary of the steps in embodiments of the present description performed within the framework of a process as exemplified in the flow chart of FIG. 4.

It will be otherwise appreciated that the sequence of steps of FIGS. 3A to 3I and FIG. 4 is merely exemplary in so far as:

a single device 10 is illustrated being manufactured while current production processes involve a chain or string of devices manufactured simultaneously to be finally separated into individual devices 10 via a “singulation” step (e.g., cutting the chain or string between adjacent devices via a blade);

one or more steps illustrated can be omitted, performed in a different manner (with other tools, for instance) and/or replaced by other steps;

additional steps and may be added;

one or more steps can be carried out in a sequence different from the sequence illustrated.

Also, unless the context indicates differently, the individual steps illustrated in FIG. 3A to 3I and FIG. 4 can be performed in a manner known to those of skill in the art, which makes it unnecessary to provide a more detailed description of these individual steps.

FIG. 3A is exemplary of a substrate (leadframe) 12 including a die pad 12A and leads 12B being laminated on a film/tape T (block 100 in the flow-chart of FIG. 4).

FIG. 3B is exemplary of a first semiconductor chip or die 141 (e.g., a low-power controller chip) being attached onto the die pad 12A via die attach material 1410 such as a die attach glue (block 101 in FIG. 4).

FIG. 3C is exemplary of a first wire bonding pattern 161 (of, e.g., copper wire) being formed to provide electrical connection of the chip 141 to selected ones of the leads 12B according to a desired routing pattern (block 102 in FIG. 4).

FIG. 3D is exemplary of a first mass 181 of package molding compound (an epoxy resin, for instance) being (half) molded, e.g., via film-assisted molding, onto the chip 141 attached on the die pad 12A and the associated wire bonding pattern 161 to provide an insulating encapsulation thereof (block 103 in FIG. 4).

As illustrated, the (at least one) die pad 12A in the leadframe 12 and leads 12B in the array of electrically conductive leads arranged around the die pad 12A have separation (insulation) spaces therebetween.

As visible in FIG. 3D, the mass of encapsulating material 181 molded onto the leadframe having the semiconductor chip 141 attached thereon and coupled to electrically conductive leads 12B in the array of electrically conductive leads via the first pattern of electrically conductive formations (wire bonding) 161 penetrates into (and practically fills) these separation spaces.

This was found to be beneficial in facilitating good anchoring of the molding material 181 to the leadframe 12.

After removal of the film/tape T and cleaning, e.g., plasma cleaning (blocks 104 and 105 in FIG. 4) the assembly previously formed is turned over (“flipped”) as indicated by the arrow labeled LF in FIG. 4 thus assuming the “leadframe up” orientation illustrated in FIG. 3E taking.

At this point, a sequence of steps as previously performed at one side of the leadframe 12 is repeated at the other, opposite side of the leadframe.

FIG. 3F is exemplary of a second semiconductor chip or die 142 (e.g., a power chip) being attached onto the die pad 12A via die attach material 1420 such as a die attach glue (block 106 in FIG. 4).

FIG. 3G is exemplary of a second wire bonding pattern 162 (of, e.g., aluminum wire) being formed to provide electrical connection of the chip 142 to selected ones of the leads 12B according to a desired routing pattern (block 107 in FIG. 4).

Advantageously, the wire-bonding pattern 162—the second wire bonding pattern provided in the sequence illustrated herein, after the wire bonding pattern 161 — comprises (consists essentially of) aluminum wire applied via an ultrasonic wire bonding technique.

This option was found to facilitate avoiding undesired negative effects on the already existing structure onto which this (second) wire bonding is provided.

FIG. 3H is exemplary of a second mass 182 of package molding compound (an epoxy resin, for instance) being (half) molded (e.g., via standard molding) onto the chip 142 attached on the die pad 12A and the associated wire bonding pattern 162 to provide an insulating encapsulation thereof (block 108 in FIG. 4).

As discussed previously, the die pad 12A and the leads 12B in the leadframe 12 have separation spaces therebetween into which the mass of encapsulating material 181 has previously penetrated so that these separation spaces are practically filled by the encapsulating material 181.

Penetration of the encapsulating material 182 into these separation spaces is thus countered by the material 181 already penetrated therein. An interface between the materials 181, 182 will however be formed at these separation spaces capable of contributing to good anchoring of the whole encapsulation 181, 182 to the leadframe 12.

This will be the case also when the materials 181, 182 are different, e.g., with the material 181 being a resin having a higher melting temperature than the material 182 so that the material 181 will be hardly (if at all) affected by the material 182 being molded onto the other side of the leadframe 12.

It will be otherwise appreciated that even in the case the materials 181, 182 are the same (e.g., a same resin), an interface therebetween at these separation spaces between the die pad 12A and the leads 12B will be detectable resulting from the two masses 181, 182 having been molded at different times (e.g., with the encapsulation 181 already solidified at the time the encapsulation 182 is molded onto the opposite side of the leadframe 12). That is, even if of the same material, the two masses 181, 182 will be generally detectable as distinct masses.

Also, in certain examples, the two masses 181, 182 can be distinguished by the fact that they include (even in a same base resin) filler particles of different sizes in the mass 181 and in the mass 182.

The blocks labeled 109 to 112 in the flow chart of FIG. 4 are exemplary of steps such as post-mold cure (PMC), first crop dambar cut, solder plating, second crop singulation (performed as conventional in the art) that result in a final “double-deck” device structure as illustrated in FIG. 31 (this is essentially identical to FIG. 1).

The sequence of FIGS. 3A to 3I and the flow chart of FIG. 4 are thus exemplary of a first set of operations and a second set of operations.

In the examples presented herein the first set of operations is performed with the leadframe 12 kept in a first spatial orientation (FIGS. 3A to 3D, with the leadframe 12 supported by the underlying tape/film T), to facilitate operating from above the leadframe 12.

In the examples presented herein the first set of operations comprises in the first place attaching (e.g., via a glue 1410) a first semiconductor chip 141 to a first surface of the leadframe 12.

A first pattern of electrically conductive formations (wire bonding pattern 161) is then provided coupling the first semiconductor chip 141 (e.g., at top-side conductive pads not visible for scale reasons) to electrically conductive leads in the array of electrically conductive leads 12B.

A first mass 181 of encapsulating material in then molded onto the first surface of the leadframe 12 having the first semiconductor chip 141 attached thereon and coupled to electrically conductive leads 12B in the array of electrically conductive leads via the first wire bonding pattern 161.

The first mass 181 of encapsulating material (once solidified via heat or UV curing, as conventional in the art) provides a protective encapsulation of the first semiconductor chip 141 and the first wire bonding pattern 161.

As illustrated, the first mass 181 of encapsulating material is molded in such a way to leave uncovered the second surface of the leadframe 12, opposite the first surface onto which the first semiconductor chip 141 has been attached.

For instance, in FIG. 3D the second surface of the leadframe 12 (facing downwards) is covered by the tape/film T, which is removed. In any case, even when the tape/film T is removed, the first mass 181 of encapsulating material does not extend over the second surface of the leadframe 12.

As exemplified in FIG. 3E, the leadframe 12 with the first semiconductor chip 141 and the first wire bonding 161 protected by the first encapsulation 181 can be turned over (LF in FIG. 4) so that a second set of operations can be performed with the leadframe 12 kept in a second spatial orientation (“leadframe up”: see FIGS. 3E to 31), opposite the first one, again to facilitate operating from above the leadframe 12.

In the examples presented herein the second set of operations comprises attaching (again, e.g., via a glue 1420) a second semiconductor chip 142 to the second surface of the leadframe 12 left uncovered by the first mass 181 of encapsulating material with the first semiconductor chip 141 and the first wire bonding pattern 161 encapsulated by the first mass 181 of encapsulating material.

A second wire bonding pattern 162 can thus be provided in order to couple the second semiconductor chip 142 (e.g., at top-side conductive pads not visible for scale reasons) to electrically conductive leads 12B in the array of electrically conductive leads of the leadframe 12.

A second mass 182 of encapsulating material is then molded onto the second surface of the leadframe 12 having the second semiconductor chip 142 attached thereon and coupled to electrically conductive leads in the array of electrically conductive leads 12B via the second wire bonding pattern 162.

The second mass 182 of encapsulating material thus completes the device package by providing a protective encapsulation of the second semiconductor chip 142 and the second wire bonding pattern 162.

As noted, the first mass 181 of encapsulating material and the second mass 182 of encapsulating material can be either a same material or different materials; in the latter case the first mass 181 of encapsulating material may optionally have a higher melting temperature than the second mass 182 of encapsulating material. In that way the material 181 will be hardly (if at all) affected by the material 182 being molded onto the other side of the leadframe 12.

As noted, the first wire bonding 161 and the second wire bonding pattern 162 can be of different electrically conductive materials, optionally copper (first wire bonding 161) and aluminum (second wire bonding, 162), respectively. Optionally, the second wire bonding pattern 162 can be provided via ultrasonic bonding.

Either or both of these features (aluminum as the wire material and/or ultrasonic bonding) were found beneficial in avoiding that providing the second wire bonding 181 may adversely affect the first semiconductor chip 141 and the first wire bonding 181 already in place on the other side of the leadframe 12.

Without prejudice to the underlying principles, the details and embodiments may vary, even significantly, with respect to what has been described in the foregoing, by way of example only, without departing from the extent of protection.

The claims are an integral part of the technical teaching on the embodiments as provided herein.

The extent of protection is determined by the annexed claims.

1. A method, comprising:
attaching a first semiconductor integrated circuit chip to a first surface of a leadframe, wherein the leadframe includes an array of electrically conductive leads;
providing a first pattern of electrically conductive formations coupling the first semiconductor integrated circuit chip to electrically conductive leads in the array of electrically conductive leads;
molding a first mass of encapsulating material onto the first surface of the leadframe having the first semiconductor integrated circuit chip attached thereon and coupled to electrically conductive leads in the array of electrically conductive leads via the first pattern of electrically conductive formations;
wherein the first mass of encapsulating material provides a first protective encapsulation of the first semiconductor integrated circuit chip and the first pattern of electrically conductive formations, and wherein a second surface of the leadframe opposed to the first surface of the leadframe is left uncovered by the first mass of encapsulating material;
attaching a second semiconductor integrated circuit chip to the second surface of the leadframe left uncovered by the first mass of encapsulating material with the first semiconductor integrated circuit chip and the first pattern of electrically conductive formations encapsulated by the first mass of encapsulating material;
providing a second pattern of electrically conductive formations coupling the second semiconductor integrated circuit chip to electrically conductive leads in the array of electrically conductive leads;
molding a second mass of encapsulating material onto the second surface of the leadframe having the at least one second semiconductor integrated circuit chip attached thereon and coupled to electrically conductive leads in the array of electrically conductive leads via the second pattern of electrically conductive formations;
wherein the second mass of encapsulating material provides a second protective encapsulation of the second semiconductor integrated circuit chip and the second pattern of electrically conductive formations.

2. The method of claim 1, wherein the leadframe comprises a die pad and wherein the electrically conductive leads in the array of electrically conductive leads are arranged around the die pad with separation spaces therebetween, wherein the first mass of encapsulating material molded onto the first surface of the leadframe having the first semiconductor integrated circuit chip attached thereon at said die pad and coupled to electrically conductive leads in the array of electrically conductive leads via the first pattern of electrically conductive formations penetrates into said separation spaces.

3. The method of claim 1, wherein the first mass of encapsulating material and the second mass of encapsulating material are made of different materials.

4. The method of claim 3, wherein the material of the first mass of encapsulating material has a higher melting temperature than the material of the second mass of encapsulating material.

5. The method of claim 1, further comprising providing the first pattern of electrically conductive formations and the second pattern of electrically conductive formations as wire bonding patterns.

6. The method of claim 1, wherein:
the first pattern of electrically conductive formations and the second pattern of electrically conductive formations are made of different electrically conductive materials.

7. The method of claim 6, wherein the different electrically conductive materials are copper for the first pattern of electrically conductive formations and aluminum for the second pattern of electrically conductive formations.

8. The method of claim 1, wherein:
providing the second pattern of electrically conductive formations comprises ultrasonic bonding of the second semiconductor chip to electrically conductive leads in the array of electrically conductive leads.

9. The method of claim 1, further comprising:
positioning the leadframe in a first spatial orientation when performing said steps of attaching the first semiconductor integrated circuit chip to the first surface of the leadframe, providing the first pattern of electrically conductive formations and molding the first mass of encapsulating material onto the first surface of the leadframe; and
turning the leadframe over with the first semiconductor integrated circuit chip and the first pattern of electrically conductive formations encapsulated by the first mass of encapsulating material to a second spatial orientation, opposite the first spatial orientation; and
with the leadframe in said second spatial orientation, performing said steps of attaching the second semiconductor integrated circuit chip to the second surface of the leadframe, providing the second pattern of electrically conductive formations and molding the second mass of encapsulating material onto the second surface of the leadframe.

10. The method of claim 1, further comprising:
supporting the leadframe via a laminar substrate at the second surface of the leadframe opposed to the first surface of the leadframe while performing said steps of attaching the first semiconductor integrated circuit chip to the first surface of the leadframe, providing the first pattern of electrically conductive formations and molding the first mass of encapsulating material onto the first surface of the leadframe ;
wherein the laminar substrate counters covering of said second surface of the leadframe by the first mass of encapsulating material; and
separating the laminar substrate from the leadframe subsequent to molding the first mass of encapsulating material onto the first surface of the leadframe.

11. The method of claim 1, further comprising embedding a heat spreader into at least one of the first mass of encapsulating material and the second mass of encapsulating material.

12. A semiconductor device, comprising:
a first semiconductor integrated circuit chip attached to a first surface of a leadframe, wherein the leadframe includes an array of electrically conductive leads;
a first pattern of electrically conductive formations coupling the first semiconductor integrated circuit chip to electrically conductive leads in the array of electrically conductive leads;
a first mass of encapsulating material molded onto the first surface of the leadframe to provide a protective encapsulation of the first semiconductor integrated circuit chip and the first pattern of electrically conductive formations;
wherein a second surface of the leadframe opposed to the first surface of the leadframe is not covered by the first mass of encapsulating material;
a second semiconductor integrated circuit chip attached to the second surface of the leadframe which is not covered by the first mass of encapsulating material;
a second pattern of electrically conductive formations coupling the second semiconductor integrated circuit chip to electrically conductive leads in the array of electrically conductive leads; and
a second mass of encapsulating material molded onto the second surface of the leadframe to provide a protective encapsulation of the at least one second semiconductor chip and the second pattern of electrically conductive formations;
wherein the second mass of encapsulating material is distinct from the first mass of encapsulating material.

13. The semiconductor device of claim 12:
wherein the leadframe comprises die pad with electrically conductive leads in the array of electrically conductive leads arranged around the die pad with separation spaces therebetween; and
wherein the first mass of encapsulating material penetrates into said separation spaces.

14. The semiconductor device of claim 12, wherein the first mass of encapsulating material and the second mass of encapsulating material are made of different materials.

15. The semiconductor device of claim 14, wherein the material of the first mass of encapsulating material preferably has a higher melting temperature than the material of the second mass of encapsulating material.

16. The semiconductor device of claim 12, wherein the first pattern of electrically conductive formations and the second pattern of electrically conductive formations are made of different electrically conductive materials.

17. The semiconductor device of claim 16, wherein the material of the first pattern of electrically conductive formations is copper and the material of the second pattern of electrically conductive formations is aluminum.

18. The semiconductor device of claim 12, further comprising an ultrasonic bond between the second pattern of electrically conductive formations of the second semiconductor integrated circuit chip and the electrically conductive leads in the array of electrically conductive leads.

19. The semiconductor device of claim 12, wherein the first pattern of electrically conductive formations comprise first wire bonds and the second pattern of electrically conductive formations comprise second wire bonds.

20. The semiconductor device of claim 12, further comprising a heat spreader embedded in one or more of the first mass of encapsulating material and the second mass of encapsulating material.
